(19) United States
(12) Patent Application Publication
(10) Pub. No.: US 2011/0214710 A1
(43) Pub. Date: Sep. 8, 2011

(54) SOLAR COLLECTION DEVICE WITH NON-MOVING CONCENTRATION ELEMENTS

(75) Inventor: Pranjal Bodh Gupta, Auburn, AL (US)

(73) Assignee: Bluerange, LLC., Auburn, AL (US)

(21) Appl. No.: 13/039,112

(22) Filed: Mar. 2, 2011

Related U.S. Application Data
(60) Provisional application No. 61/310,544, filed on Mar. 4, 2010.

(51) Int. Cl. H01L 31/052

(52) U.S. Cl. 136/246

(57) ABSTRACT

Methods and devices are provided for solar collection and concentration using non-moving concentration elements using lens-fragments. The methods and devices improve solar collection especially at morning and evening hours when the devices and methods are used on the surface of the earth.

### CROSS REFERENCE TO RELATED APPLICATIONS

This patent application claims the benefit of the U.S. Provisional patent application Ser. No. 61/310,544 filed on Mar. 4, 2010 which is incorporated here by reference in its entirety.

### BACKGROUND

Current challenges with the photovoltaic systems: Current photovoltaic electricity is much more expensive than that from traditional power plants. For example, photovoltaic electricity costs about $0.30/kWh which is significantly higher than $0.10/kWh from conventional electricity sources. Even with complete CO₂ capture and sequestration, the electricity from coal-based power plants is not likely to exceed $0.20/kWh. Hence, the solar panels are too expensive to be able to compete with the traditional power, without any government assistance. For a wide spread commercial utilization of solar energy, the cost of electricity produced needs to be brought down significantly.

The problem of high solar electricity cost can be thought of in another terms as the solar panels are utilized only for about 6 hours each day when the sun rays directly fall on the panel. Tracking of the sun can increase the useful hours, but this option significantly adds to the cost. Outdoor moving devices are marred with failures due to weather including rain, storm, dust, snow, hails, and heat. Hence, any solar concentrator used should be static type (i.e., non-moving) so that the installations can last for about 20 years without significant maintenance.

The concentrating photovoltaic systems use lenses or mirrors to concentrate sunlight onto the solar panel. Thus a small area of solar cells can process a high amount of sunlight. There are a number of concentrator designs available utilizing reflective mirrors and/or Fresnel lenses. Unfortunately, the sunlight concentration also increases the temperature of the solar panel, reducing its conversion efficiency; as the sunlight-to-electricity conversion efficiency decreases with the temperature of operation. Hence, many of these concentrator designs require cooling mechanisms. For distributed roof-top installations, simple non-tracking solar concentrators are needed that do not overheat the panel.

### SUMMARY OF THE INVENTION

A solar collection device comprising a collection element and a concentration element is described wherein the concentration element comprises at least a lens-fragment positioned such that a light with an incidence angle up to 90 degrees is bent onto the collection element.

In another embodiment, a solar collection device comprising a collection element and a concentration element is described wherein the concentration element is directly attached to the collection element.

In yet another embodiment, a solar collection device comprising a collection element and a concentration element that comprises at least two lens-fragments is described wherein the concentration element has a lower shadow of the lens than a concentration element comprising a full lens of comparable area.

The concentration element in the described devices is not moving with respect to the collection element.

The lens-fragments used in various embodiment of the present invention are obtained from a full lens or made independently using casting or molding. The concentration element used in various embodiment of the present invention is out of plane with the collection element and in a specific embodiment, it is out of plane by 90 degrees.

The concentration element used in various embodiment of the present invention does not substantially affect a light incident at zero degree incidence angle. In a preferred embodiment, it does not affect the light incident at zero degree incidence angle at all.

In various embodiments of the present invention, the collection element is not over heated during the light incident at zero incidence angle.

The collection devices of various embodiments of the present invention can be attached to a battery, a photovoltaic cell, a heating device, an optical device, a light sensor, an electronic circuit, a satellite, and a semi-conductor.

Methods of making and using the devices of various embodiments of the present invention are also described. A method of solar collection in a solar collection device by positioning at least one lens-fragment between a collection element and a light source such that any light with an incidence angle up to 90 degrees is bent on the collection element is described.

A method of concentrating incident light in a solar collection device by directly attaching a concentration element on the collection element wherein the concentration element comprises at least one lens-fragment is described.

A method of reducing the shadow of the concentrating element on a solar collection device by providing at least one lens-fragment as the concentrating element is described.

The methods to attach the collection device to an element selected from the group consisting of a battery, a photovoltaic cell, a heating device, an optical device, a light sensor, an electronic circuit, a satellite and a semi-conductor are described.

### BRIEF DESCRIPTION OF THE DRAWINGS

FIG. 1 illustrates a full Fresnel lens in which fragments A, B, C and D are marked for cutting.

FIG. 2 illustrates lens-fragments A, B, C and D for use in concentration element

FIG. 3a illustrates placement of one lens-fragment

FIG. 3b illustrates placement of two lens-fragments

FIG. 3c illustrates placement of three lens-fragments

FIG. 3d illustrates placement of four lens-fragments

FIG. 4a illustrates concentration element bending morning sun rays onto the collection element

FIG. 4b illustrates concentration element does not affect noon time sun rays

FIG. 4c illustrates concentration element bending evening sun rays onto collection the element

### DETAILED DESCRIPTION OF THE INVENTION

### Definitions:

Lens-fragment means a portion of a complete lens. In a conventional lens the optical axis passes through center. A lens-fragment is obtained by cutting a portion of a lens so that the optical axis does not pass through the center of the piece. Hence, lens fragment can be used to bend light in an asymmetric fashion.

Shadow of the lens means a convex lens collects the entire incident light and directs toward the focal point. Hence, the points away from the focal point experience a lower intensity of light as compared to when the lens was absent. This lack of light at non-focal points is referred to as shadow of the lens.

Collection element means Collection element is referred to a device on which sun rays are collected; for example, photovoltaic solar cells.

Concentration element means is a lens or a portion thereof, that bends or concentrates the incident light onto a collection element.

Incidence angle means the angle between the light ray and the perpendicular to the surface. Incident angle is a measure to geometric angle made by sun rays onto the collection element. For example, in the case of a collection element kept horizontally at equator, the angle at sunrise is about 90°, angle at noon time is about 0°, and angle at sunset is about 90°.

The full convex lens can only bend light towards it focal point at the center. When full lens is used, a significant shadow of the lens can fall on the collection element. In the case of lens-fragment, the placement can be so chosen that the shadow of lens-fragment fall outside the collection element.

The shadow of lens has a lower light intensity on the collection element than that without using the lens. Hence, the area under the shadow will have less light due to the placement of lens, which is counter to the objective of concentrating light for increased collection.

In the proposed design, the light that falls parallel to the concentration element (say during the noon time) does not get affected. In such case, concentration does not take place, which is beneficial as overheating of the collection element is avoided, while keeping the adequately high natural light intensity.

In the present invention, the lens fragments are fixed to the collection element so that they are most effective during the morning and evening hours. Whereas during noon time, the collection element receives un-concentrated light. The lens are not moving and do not require tracking of sun. This simplifies the operation as it does not need energy for movement, elaborate motors, or the extensive outdoor maintenance that arise due to moving machine parts.

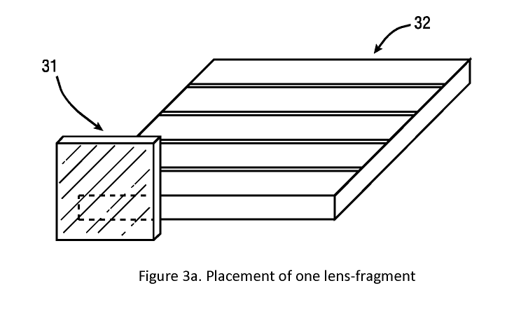

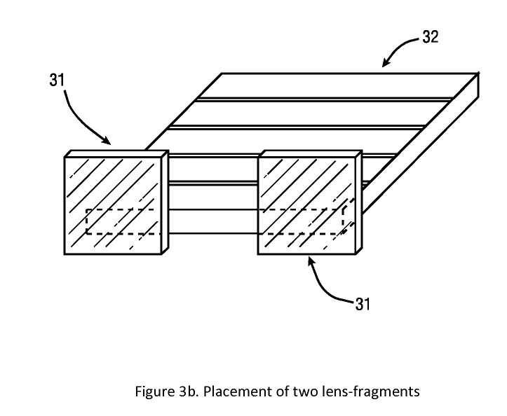

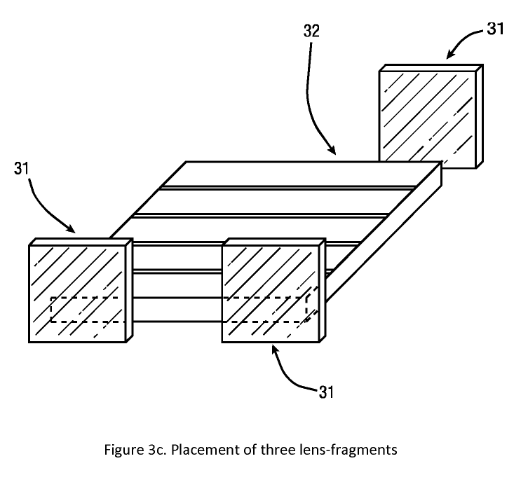

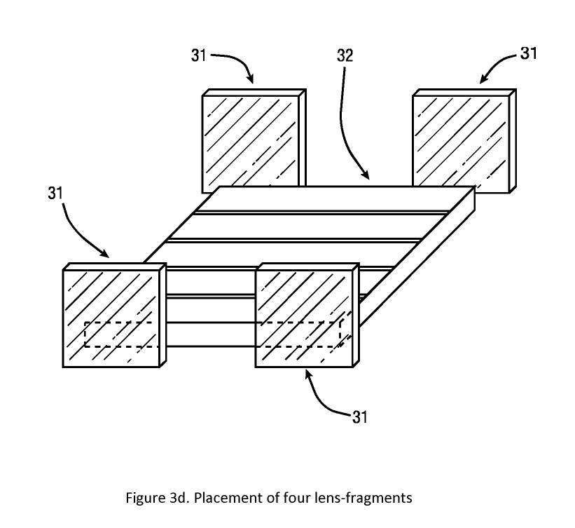

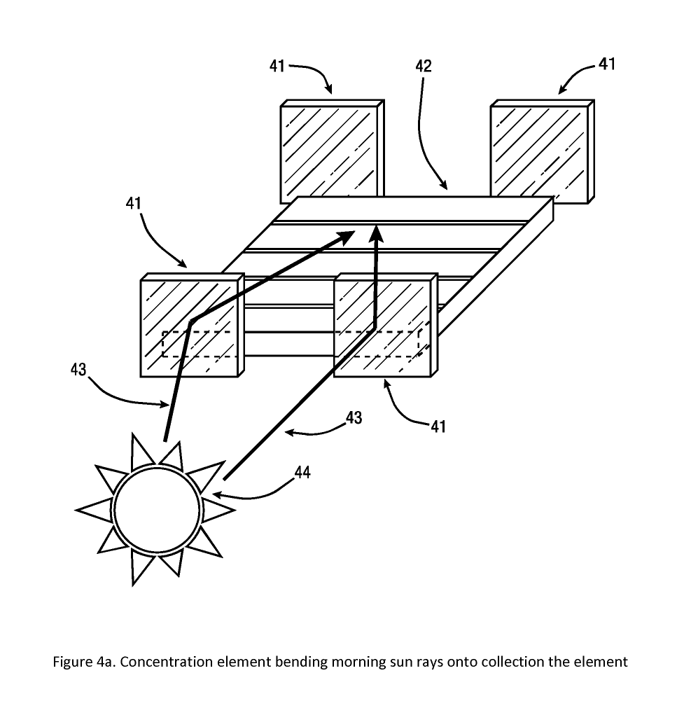

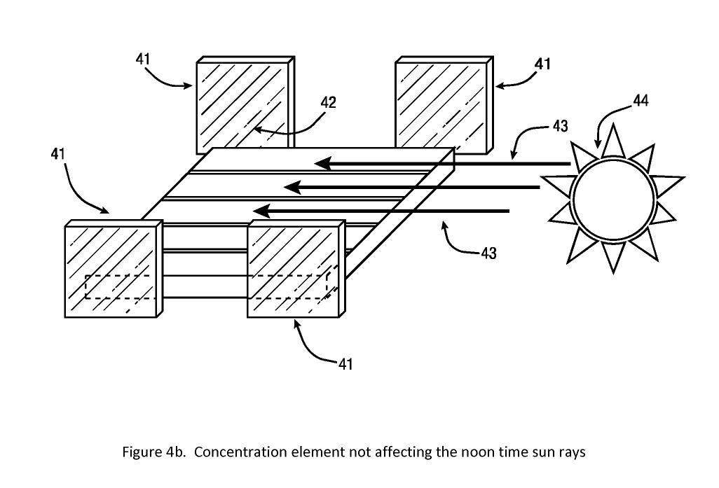

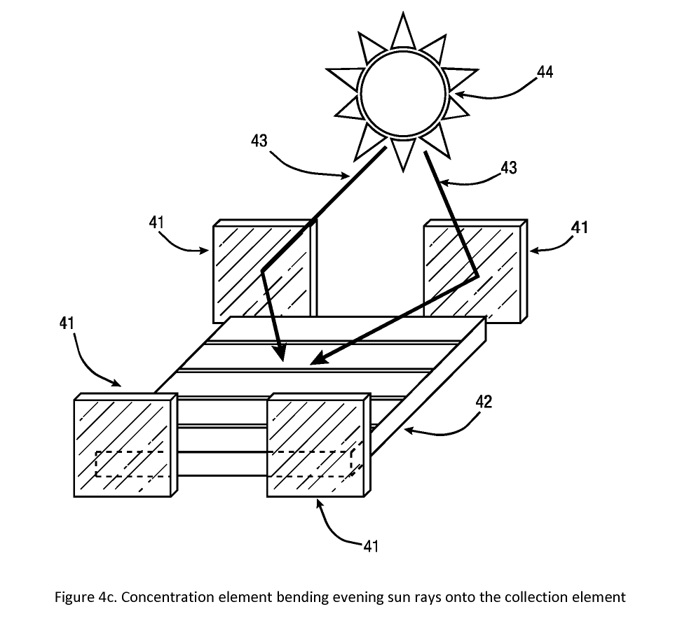

Lens-fragments(31) can be positioned at the East and West corners of the collection element(32) as shown in FIGS. 3a-3d. During the morning hours, lens-fragments(41) placed in the East bend light onto the collection element(42) as shown in FIG. 4a. During the noon time, the lens-fragments(41) do not affect the incident light as shown in FIG. 4b. During the evening hours, lens-fragments(41) placed in the West bend light onto the collection element(42) as shown in FIG. 4c.

It is advantageous to attach the lens directly to the collection element, to avoid the extra cost of extender structure in the case of lens that are fixed at some distance using a mounting mechanism suitable for outdoor use. In some embodiments of the present invention, the lens-fragments are directly attached to the East and West ends of the collection element, which avoids excessive mounting cost.

The concentrating lens causes increase in the light intensity at the optical axis accompanied with a corresponding decrease in the light intensity in the area away from the optical axis. The loss of light intensity away from the optical axis is known as the shadow of lens. By use of lens-fragment, asymmetric concentration of light can be achieved at the collection element, and the much of the shadow can be allowed to fall outside the collection element making the shadow of the lens less relevant.

In the case of sun tracking concentration elements, moving mechanisms are employed. Such mechanisms are expensive to build for outdoor use and require extensive maintenance or energy for operation. The present invention avoids the use of any moving mechanism. The bending of light is done by separate sets of lens fragments in the morning and evening hours, respectively,

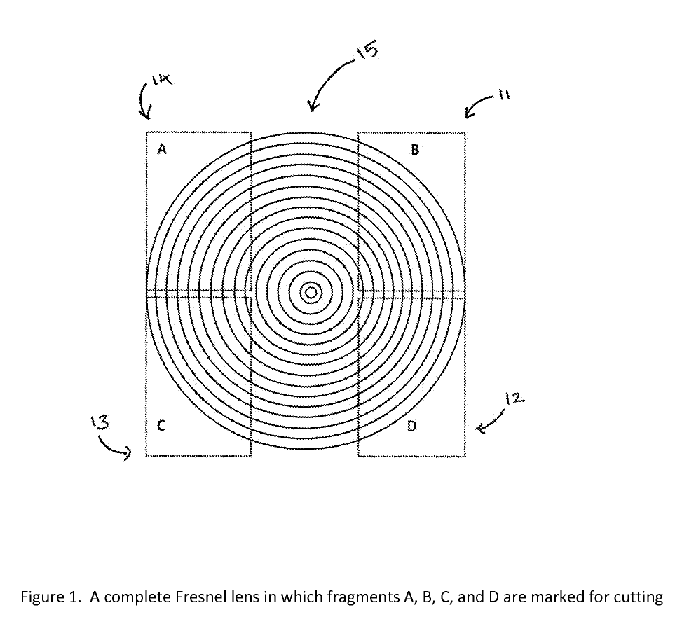

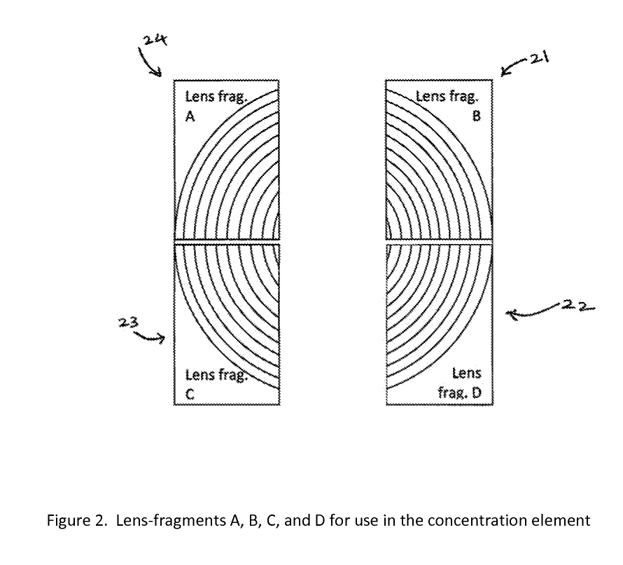

A complete Fresnel lens(15) is shown in FIG. 1, with its optical axis in the center. Four areas(11,12,13,14) for cutting the lens are marked in FIG. 1. Various lens fragments (21, 22, 23, 24) are shown in FIG. 2. Each lens-fragment will bend and concentrate light rays toward the optical axis of the parent lens. Hence, a suitable placement on collection element for lens fragment A is South East corner, for lens fragment B is North East corner, for lens fragment C is South West corner, and for lens fragment D is North West corner.

In U.S. Pat. No. 6,958,868 FIGS. 24a and b, the Fresnel lens used seems to have optical axis in the center of the lens, which is different than the proposed fragments here. But, it may be possible, by use of strong electrical field to alter the optical properties in U.S. Pat. No. 6,958,868 to make the lenses asymmetric. As such, the present invention can be used with prior inventions to derive broad utility.

Concentration element can be mounted on the East and West ends, preferably at South and North corners, of the collection element as shown in FIGS. 3a-d. In FIG. 3a, the two elements are attached at 90° angle; however other angles can also be used. Variation in the attachment angle can be practiced to optimize the overall production of electricity for a given solar conditions and the device location.

Typically capacity of the collection element is designed for a maximum radiation which occurs at noon time. Hence, the concentration during the noon time may not provide significant benefit to the collection element. On the contrary ensuing overheating can reduce the efficiency of the photovoltaic cells. In the proposed invention, the light near noon time is not concentrated which avoids possible overheating of the collection element.

The present device can be beneficially connected to photovoltaic cells to increase daily electricity production, to solar thermal devices to obtain more heat, to light sensors to increase the sensing region or angle, to optical devices to widen their angle of coverage, etc. For a given collection device, the size, placement, and arrangement of lens-fragments can be optimized to obtain the best performance. For example, the length and width of the lens-fragment can be varied in relation to the size of concentration device; here an increase in the surface area will increase the amount of solar radiation being bent toward the concentration device. The distance of the lens-fragment from the edge of the collection device can be varied to reduce the shadow and increase the concentrated light on the collection device. A suitable arrangement of a single or multiple lens-fragments at the corners and edges of the collection device can be practiced to gain an optimum performance of the system.

The key embodiment of the invention is to use light bending lens fragments as concentrating elements so that there is an increase in the light intensity and/or duration of light falling onto the collection elements. The invention uses non-moving lens fragments that are attached to the collection element. Lens-fragments are cut from Fresnel lenses or non-Fresnel lenses so that each lens-fragment can bend light in an asymmetric fashion. Alternatively, the lens-fragment can be directly produced from the raw material by using suitable mold(s).

Further utility may be derived by attaching the collection device to a battery, a photovoltaic cell, a heating device, an optical device, a light sensor, an electronic circuit, a satellite and a semi-conductor.

1. A solar collection device comprising a collection element and a concentration element wherein the concentration element comprises at least a lens-fragment positioned such that a light with an incidence angle up to 90 degrees is bent onto the collection element.

2. A solar collection device comprising a collection element and a concentration element wherein the concentration element is directly attached to the collection element.

3. A solar collection device comprising a collection element and a concentration element that comprises at least two lens-fragments wherein the concentration element has a lower shadow of the lens than a concentration element comprising a full lens of comparable area.

4. The device of claim 1 wherein the concentration element is not moving with respect to the collection element.

5. The device of claim 1 wherein the at least one lens-fragment is obtained from a full lens or made independently.

6. The device of claim 2 wherein the concentration element is out of plane with the collection element.

7. The device of claim 2 wherein the concentration element is out of plane with the collection element by 90 degrees.

8. The device of claim 2 wherein the concentration element comprises at least one lens-fragment or the device of claim 1 wherein a light incident at zero degree incidence angle is substantially unaffected.

9. The device of claim 1 wherein the collection element is not over heated during the light incident at zero incidence angle.

10. The device of claim 1 further attached to an element selected from the group consisting of a battery, a photovoltaic cell, a heating device, an optical device, a light sensor, an electronic circuit, a satellite and a semi-conductor.

11. A method of solar collection in a solar collection device by positioning at least one lens-fragment between a collection element and a light source such that any light with an incidence angle up to 90 degrees is bent on the collection element.

12. A method of concentrating incident light in a solar collection device by directly attaching a concentration element on the collection element wherein the concentration element comprises at least one lens-fragment.

13. A method of reducing the shadow of the concentrating element in a solar collection device by providing at least one lens-fragment as the concentrating element.

14. The method of claim 11 wherein the concentration element is not moving with respect to the collection element.

15. The method of claim 11 wherein the at least one lens-fragment is obtained from a full lens.

16. The method of claim 12 wherein the concentration element is out of plane with the collection element.

17. The method of claim 12 wherein the concentration element is out of plane with the collection element by 90 degrees.

18. The method of claim 11 wherein a light incident at zero degree incidence angle is substantially unaffected.

19. The method of claim 11 wherein the collection element is not over heated during the light incident at zero incidence angle.

20. The method of claim 11 further comprising a step of attaching the collection device to an element selected from the group consisting of a battery, a photovoltaic cell, a heating device, an optical device, a light sensor, an electronic circuit, a satellite and a semi-conductor.
